(19) United States
(12) Patent Application Publication
(10) Pub. No.: US 2025/0006820 A1
(43) Pub. Date: Jan. 2, 2025

(54) TUNNEL NANOSHEET FET FORMATION WITH INCREASED CURRENT

(71) Applicant: INTERNATIONAL BUSINESS MACHINES CORPORATION, ARMONK, NY (US)

(72) Inventors: Min Gyu Sung, Latham, NY (US); Liqiao Qin, Albany, NY (US); Julien Frougier, Albany, NY (US); Ruilong Xie, Niskayuna, NY (US)

(21) Appl. No.: 18/343,712

(22) Filed: Jun. 28, 2023

(51) Int. Cl. H01L 29/66; H01L 21/8238; H01L 27/092; H01L 29/06; H01L 29/08; H01L 29/423; H01L 29/775; H01L 29/786

(52) U.S. Cl. CPC H01L 29/66977; H01L 21/823807; H01L 27/092; H01L 29/0673; H01L 29/0847; H01L 29/42392; H01L 29/66439; H01L 29/775; H01L 29/78696

(57) ABSTRACT

A Tunnel Field-Effect Transistor (TFET) device, an isolating layer over a substrate layer, a gate stack above the isolating layer, a source and a drain region over the isolating layer, a channel region underneath the gate stack, and a plurality of nanosheets in the channel region protruding from the source region. Each nanosheet of the plurality of nanosheets includes source region material encapsulated by a narrow band gap material.

### BACKGROUND

### Technical Field

The present disclosure generally relates to transistors and, more particularly, to tunnel nanosheet field-effect transistors and methods of creation thereof.

### Description of the Related Art

In recent semiconductor device fabrication processes, a large number of semiconductor devices, such as n-type field effect transistors (nFETs) and p-type field effect transistors (pFETs), are fabricated on a single wafer. Non-planar transistor architectures such as fin-type FETs (FinFET) and nanosheet (or nanowire) transistors can provide increased device density and increased performance over planar transistors. FinFETs are non-planar, three-dimensional (3D) transistors that include a fin-shaped channel with a gate formed along the sidewalls and top surface of the fin channel. Nanosheet transistors are non-planar, 3D transistors that include a gate stack wrapped around the full perimeter of multiple nanosheet channel regions for improved control of channel current flow. Nanosheet transistor architectures enable fuller depletion in the nanosheet channel regions and reduce short-channel effects.

### SUMMARY

According to an embodiment, a Tunnel Field-Effect Transistor (TFET) device includes a substrate layer, a gate stack, a source region and a drain region above the substrate layer, a channel region underneath the gate stack, and a plurality of nanosheets in the channel region protruding from the source region. Each nanosheet of the plurality of nanosheets can include a first layer encapsulated by a narrow band gap material layer, and the first layer is not in direct contact with the drain region.

In one embodiment, each nanosheet of the plurality of nanosheets is attached to the source region on the first side of the nanosheet, and a second side, a top side, and a bottom side of each nanosheet of the plurality of nanosheets are encapsulated by the channel region.

In some embodiments, at least one of the source, the drain, and the channel regions include Ge, SiGe, GaAs, InAs, or InGaAs.

In additional embodiments, two or more of the source, the drain, and the channel regions are homojunction.

In several embodiments, the source, drain, and channel regions are heterojunctions.

In an embodiment, tunneling occurs via a top surface, a bottom surface, and a side surface of each nanosheet of the plurality of nanosheets.

In one embodiment, the first layer and the source region include the same material.

In several embodiments, the thickness of the channel region is substantially 5 nanometers to substantially 10 nanometers.

According to another embodiment, a method for forming a TFET device includes forming a channel region over a substrate layer, forming a plurality of nanosheets in the channel region protruding from a source region toward a drain region, and forming the source and drain regions and a gate stack above the channel region. In some embodiments, each nanosheet of the plurality of nanosheets includes a first layer encapsulated by a narrow band gap material layer, and the first layer is not in direct contact with the drain region.

In one embodiment, forming the plurality of nanosheets includes depositing an organic planarization layer (OPL) over a drain region side, forming a plurality of recesses by selectively removing portions of sacrificial layers of the channel region from a source region side, while the drain region side is intact, removing the OPL layer, growing channel material on sidewalls of the plurality of recesses, and growing first layer materials inside the plurality of recesses to form the plurality of nanosheets.

In one embodiment, the method includes forming an insulating layer to separate the gate stack from the channel region.

In one embodiment, the plurality of nanosheets is formed by an epitaxial growth technique.

According to yet another embodiment, a TFET device can include an isolating layer over a substrate layer, a gate stack, a source and a drain region over the isolating layer, a channel region underneath the gate stack, and a plurality of nanosheets in the channel region protruding from the source region. Each nanosheet of the plurality of nanosheets can include source region material encapsulated by a narrow band gap material.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a TFET, in accordance with some embodiments.

FIG. 2A illustrates a tunnel nanosheet FET device before the formation of the transistor components, in accordance with some embodiments.

FIG. 2B illustrates a TFET device after a gate structure is formed, in accordance with some embodiments.

FIG. 2C illustrates a TFET device after the bottom dielectric isolation layer is removed, in accordance with some embodiments.

FIG. 2D illustrates a TFET device after a spacer layer is applied, in accordance with some embodiments.

FIG. 2E illustrates a TFET device after nanosheets pull down, in accordance with some embodiments.

FIG. 2F illustrates a TFET device after inner spacer formation, in accordance with some embodiments.

FIG. 2G illustrates the formation of an OPL layer over a drain side of the TFET device, in accordance with some embodiments.

FIG. 2H illustrates the TFET device after the outer layers are laterally recessed, in accordance with some embodiments.

FIG. 2I illustrates the TFET device after the OPL is removed, in accordance with some embodiments.

FIG. 2J illustrates a TFET after the inner layer is epitaxially grown inside the recesses, in accordance with some embodiments.

FIG. 2K illustrates the TFET after the source and drain regions are formed, in accordance with some embodiments.

FIG. 3 illustrates a TFET, in accordance with an embodiment.

FIGS. 4A & 4B illustrate block diagrams of a method for forming the TFET, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to Field-effect transistors (FETs) which are fundamental electronic devices that have revolutionized the field of electronics. FETs serve as building blocks for numerous electronic circuits and are widely used in various applications. FETs are based on the principle of controlling the flow of current through a semiconductor channel using an electric field generated by a gate electrode. The two most common types of FETs are Metal-Oxide-Semiconductor FETs (MOSFETs) and Junction Field-Effect Transistors (JFETs).

MOSFETs, particularly Complementary Metal-Oxide-Semiconductor (CMOS) technology, dominate the digital integrated circuit industry due to their high switching speeds, low power consumption, and scalability. CMOS technology enables the fabrication of complex integrated circuits, including microprocessors, memory chips, and digital logic circuits. These advancements have led to the proliferation of powerful computing devices, smartphones, and various portable electronics.

However, FETs also face several limitations. One significant challenge is the increasing power consumption associated with traditional CMOS scaling. As transistors become smaller, leakage currents and power dissipation become more prominent, limiting further improvements in device performance. Additionally, achieving faster switching speeds is becoming increasingly challenging due to limitations in material properties and device physics. These constraints pose significant obstacles to the continued advancement of conventional FET technology.

To address these limitations, researchers are exploring alternative transistor designs such as TFETs. TFETs leverage quantum mechanical tunneling to enable lower power consumption and improved performance compared to traditional FETs. TFETs have the potential to operate at lower supply voltages, thereby reducing power dissipation and overcoming some of the limitations of CMOS technology. However, TFETs face challenges related to design, material selection, and manufacturing processes that need to be addressed for their widespread adoption. However, narrowing the channel can significantly decrease the ability of the gate to control the TFET's operation, especially current leakage when the transistor voltage is zero.

To tackle the above-mentioned problems, disclosed is a TFET with nanosheets and enhanced tunneling area. The TFET includes a gate stack, a channel region underneath the gate stack, and a plurality of nanosheets disposed between the gate stack and the channel region. The nanosheets are doped with a first conductivity type, and the channel region is doped with a second conductivity type. The gate stack is doped with a third conductivity type that is opposite to the first conductivity type. The first, second and third conductive types can be similar or different.

The disclosed TFET can offer a low off-current and a high on-current. The low off-current can be achieved by the high energy barrier between the channel region and the substrate. The high on-current can be achieved by the tunnel effect through the nanosheets. The TFET is suitable for use in a variety of applications, such as low-power logic circuits, memory devices, and radio frequency (RF) devices.

The use of nanosheets in the TFET can increase the tunneling current by providing a shorter distance for the electrons to tunnel through. The nanosheets also have a larger surface area, which increases the number of electrons that can tunnel through at the same time.

The TFET described herein can incorporate a structure that enables efficient charge carrier transport through a tunneling mechanism. The transistor design can include a channel region with a narrow bandgap material surrounded by a gate structure. The combination of the narrow bandgap material and gate structure facilitates significant improvements in device performance, including reduced subthreshold swing, enhanced on/off current ratio, and lowered power consumption. Furthermore, the fabrication process for the TFET involves precise material deposition and etching techniques, ensuring reliable and reproducible manufacturing.

By performing the fabrication steps disclosed herein, the TFET can be fabricated with a recessed lateral source side channel, multiple channel surfaces within the trench, and the growth of a source side epi layer inside the trench, resulting in three junction areas. The drain side of the TFET remains consistent with conventional MOSFET fabrication. The combined structure and fabrication process enables the TFET to exhibit enhanced performance characteristics, including improved energy efficiency, reduced power consumption, and reduced subthreshold swing.

Accordingly, the teachings herein provide methods and systems of tunnel nanosheet FET formation with increased current. The techniques described herein may be implemented in a number of ways. Example implementations are provided below with reference to the following figures.

### Example Tunnel Nanosheet FET Structure

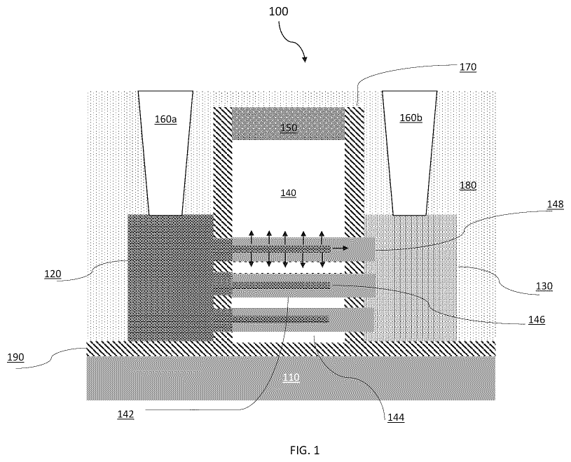

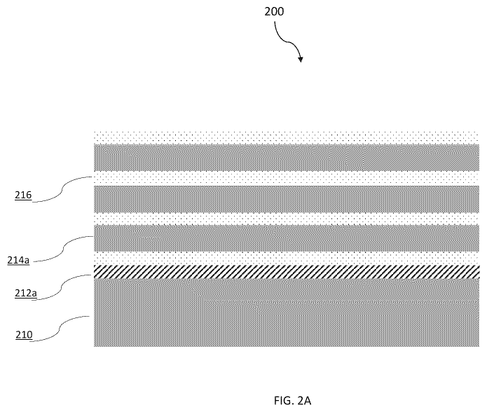

Reference now is made to FIG. 1, which is a simplified cross-section view of a tunnel FET structure 100 (hereinafter TFET device), consistent with an illustrative embodiment. The TFET device 100 can include a substrate 101, a source region 120, a drain region 130, a gate stack 140, a plurality of nanosheets 142, a gate metal 144, an inner layer 146, an outer layer 148, a capping layer 150, source and drain electrodes 160a and 160b, a spacer 170, an interlayer dielectric layer (IDL) 180, and a bottom dielectric isolation (BDI) layer 190. In various embodiments, the substrate 110 may include any suitable material or combination of materials, such as doped or undoped silicon, glass, dielectrics, etc. For example, the substrate may include a Silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

Generally, the source region 120 and the drain region 130 are two salient components that play relevant roles in the TFET device's operation. Typically, source and drain regions are regions within the semiconductor material, i.e., the TFET device 100, where the current flows in and out of the transistor. The source region 120 is the region through which the majority of charge carriers (e.g., electrons or holes) enter the channel of the TFET and is responsible for providing the current that flows through the TFET device 100. The source region 120 is typically doped to have an excess of charge carriers, creating a region with high carrier concentration. This abundance of carriers allows for the efficient injection of electrons or holes into the channel when a voltage is applied.

The drain region 130, on the other hand, is the region where the majority of charge carriers exit the channel. The drain region 130 receives the current from the channel and carries the charge away from the transistor. Similar to the source, drain region 130 is also doped to have a high carrier concentration. The doping profile in the drain region ensures that carriers can easily flow out of the channel and into the drain region.

In various embodiments, the gate stack 140 can control the flow of current through the TFET device 100. The gate stack 140 is an electrode that is separated from the channel by a thin insulating layer, such as silicon dioxide (SiO2). The gate stack 140 can play a regulating role in managing the conductivity of the channel region, determining whether the TFET device 100 is in an “on” or “off” state.

Generally, in an n-type TFET, a positive voltage applied to the gate can attract electrons from the source region toward the interface between the insulating layer and the channel. This electric field induced by the gate voltage forms a conductive channel, allowing current to flow from the source to the drain. This state is known as the “on” state of the TFET. Conversely, in a p-type TFET, a negative voltage applied to the gate attracts holes from the source region toward the interface between the insulating layer and the channel. This creates a conductive path for current flow. In this case, the TFET is also in the “on” state.

In various embodiments, a capping layer 150 is formed over the gate stack 140 to protect the gate stack 140. The capping layer 150 can be a protective layer formed on top of the transistor structure to serve multiple purposes, including passivation, protection, and enabling subsequent processing steps. The capping layer 150 can further act as a protective barrier against moisture, contaminants, and/or physical damage, prevent oxidation or corrosion of the underlying transistor components, and facilitate the long-term reliability and stability of the device. Additionally, the capping layer 150 can act as a passivation layer, reducing surface defects and trapping charges that could negatively affect TFET device performance. In some embodiments, the capping layer 150 can facilitate the integration of subsequent layers or interconnects in the TFET device fabrication process.

The nanosheets 142 can include three-dimensional structures in the gate metal 144, which protrude from the source region 120 towards the drain region 130. Each nanosheet can include an inner layer 146 encapsulated by an outer layer 148, which can be a narrow band gap material. While the inner layer 146 is in direct contact with the source region 120, the inner layer 146 is not in direct contact with the drain region 130. In various embodiments, the inner layer material is the same as the source material. In such embodiments, the inner layer 146 can be viewed as an extension of the source region 130. Encapsulating the inner layer 146 by the narrow band gap outer layer 148 can increase the tunneling area as the tunneling can take place from the top surface, the bottom surface and the sidewall of the encapsulated inner layer 146, as shown by arrows on FIG. 1. It should be noted, while the 3-dimensional tunneling can take place on each nanosheet, for the sake of simplicity, tunneling on only one of the nanosheets is shown on FIG. 1.

Two electrodes 160a and 160b, that are responsible for the flow of current through the TFET device 100 are deposited over the source and drain regions 120 and 130. Each electrode is typically located on opposite sides of the channel region and plays an essential role in the FET's operation. The source electrode 160a is a terminal from which the current enters the channel region, while the drain electrode 160b is the terminal through which the current exits the channel. The direction of current flow is determined by the type of TFET (n-type or p-type) and the bias conditions applied to the device.

The functionality of the source and drain electrodes 160a and 160b is to provide a pathway for the flow of charge carriers (i.e., electrons or holes) into and out of the channel region. When a voltage is applied between the source and drain, the voltage creates an electric field across the channel, which enables the conduction of current.

In an n-type TFET, the source electrode is typically connected to the region with an excess of electrons, known as the n-type source region. The source supplies electrons to the channel region, acting as the source of charge carriers. Conversely, the drain electrode is connected to the region with a lower concentration of electrons, known as the n-type drain region. The drain serves as a sink, collecting the electrons flowing through the channel.

In a p-type TFET, the source electrode is connected to the region with an excess of holes, known as the p-type source region. The source provides holes to the channel, acting as the source of charge carriers. The drain electrode is connected to the region with a lower concentration of holes, known as the p-type drain region. The drain serves as a sink, attracting and collecting the holes flowing through the channel.

In various embodiments, a spacer 170, which is a thin insulating, is formed between the gate stack 140 and the source/drain regions 120 and 130. The spacer 170 can provide electrical isolation between gate stack 140 and the source/drain regions 120, and 130, and prevent direct electrical contact between these regions, thereby ensuring that the gate stack 140 controls the current flow through the channel region without leakage paths or undesired short circuits.

In some embodiments, the spacer 170 can define the width or length of the channel region. In an embodiment, by adjusting the spacer's dimensions, the effective channel length or width can be tailored, influencing the TFET device's electrical characteristics and performance. Additionally, in some embodiments, the spacer can affect the capacitance between the gate and the source/drain regions. In such embodiments, by adjusting the thickness or material properties of the spacer, the capacitance can be modified, which impacts the device's switching speed, power consumption, and overall performance.

In some embodiments, an interlayer dielectric layer, IDL, 180 is used to electrically isolate different layers within the TFET device 100. The IDL 180 is typically placed between the active regions of the transistor, such as the gate, source, and drain regions, to prevent unintended electrical interactions and short circuits. The IDL 180 can provide electrical insulation and mechanical support to the various components of the TFET device 100, help maintain the integrity of the transistor's electrical properties, and prevent leakage currents or crosstalk between adjacent layers. In some embodiments, the IDL 180 can act as a protective layer, shielding the underlying components from external influences, such as moisture or contaminants, that could affect the performance and reliability of the FET.

The TFET device 100 can further include a Bottom Dielectric Isolation (BDI) layer 190, which can be utilized to electrically isolate the transistor structure from the substrate 110. The bottom dielectric isolation layer 190 can provide isolation and reduce parasitic capacitance and leakage currents between the TFET device 100 and the substrate layer 110. The bottom dielectric isolation layer 190 is a dielectric material at the bottom of the transistor structure, that can help improve TFET device 100 performance and reliability by minimizing undesirable effects such as substrate leakage and latch-up.

### Example Processes for Tunnel Nanosheet FET Structures

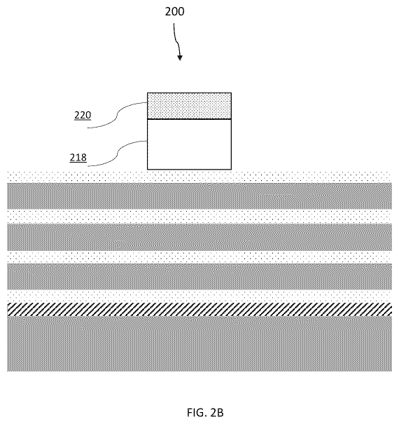

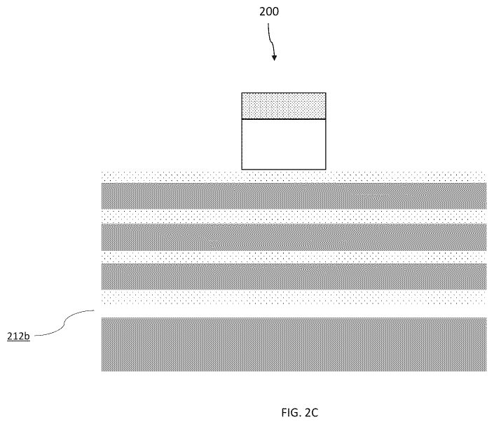

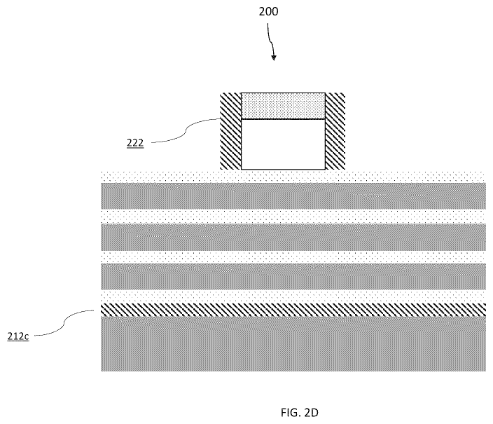

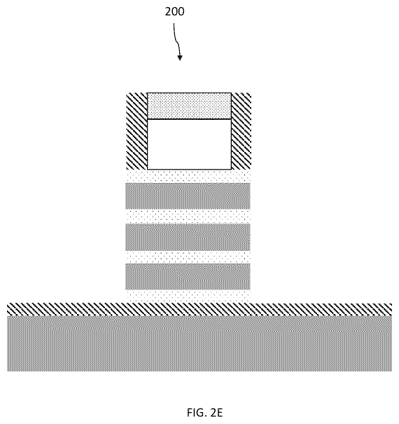

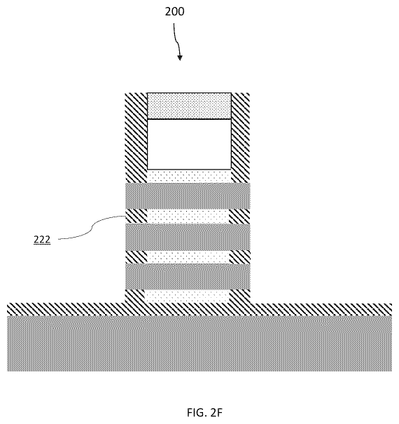

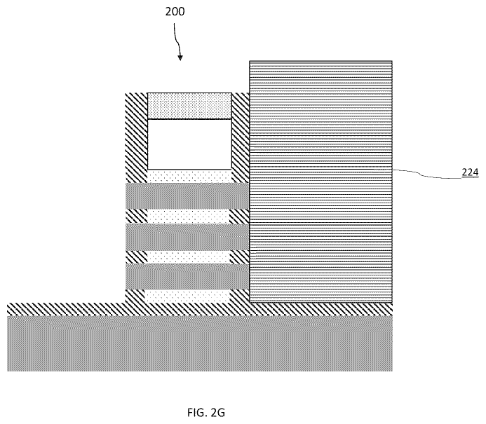

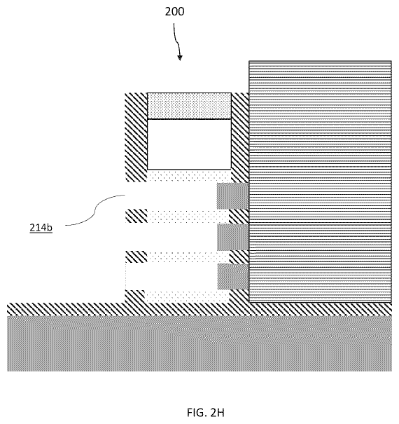

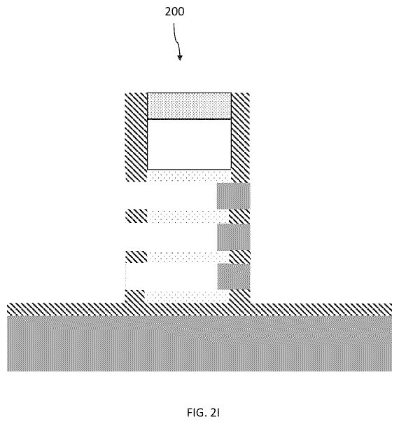

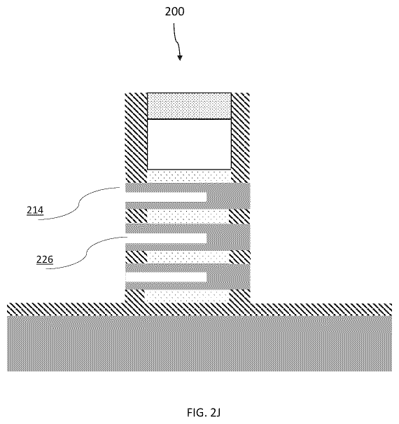

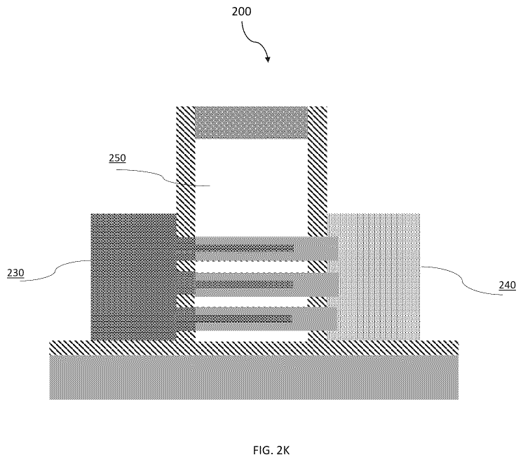

With the foregoing description of an example tunnel nanosheet FET device 100, it may be helpful to discuss an example process of manufacturing the same. To that end, FIGS. 2A to 2K illustrate various steps in the manufacture of a tunnel nanosheet FET device, consistent with illustrative embodiments. More specifically, FIG. 2A illustrates a tunnel nanosheet FET device 200 before the formation of the transistor components, consistent with an illustrative embodiment.

In the illustrative example depicted in FIG. 1, the TFET device 100 is depicted as being on a Si substrate 110, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate layer 210 is capped with the bottom dielectric isolation layer 212a and one or more alternating layers stacking on the substrate layer 210 that are further processed to form the nanosheets. In one or more embodiments, a bottom dielectric isolation layer 212a can be formed above the substrate layer 210. In one or more embodiments of the present disclosure, the bottom dielectric isolation layer 212a is a low-k dielectric. In another embodiment, the bottom dielectric isolation layer 212a can be made SiGe.

In various embodiments, forming the bottom dielectric isolation layer 212a can involve the placement of a dielectric material between the transistor and the substrate, providing insulation and preventing unwanted electrical interactions. In various embodiments, silicon dioxide (SiO2), silicon nitride (Si3N4), or a combination thereof can be used as the bottom dielectric isolation layer 212a. Such dielectric materials can exhibit high electrical insulation properties and can be deposited using techniques such as thermal oxidation, chemical vapor deposition (CVD), or physical vapor deposition (PVD).

The alternating layers can include inner layers 216 and outer layers 214a. The inner layer material can be the same as the source region material. In some embodiments, the materials used to form the inner layer 216 can include Silicon (Si), which can be heavily doped with donor impurities such as phosphorus or arsenic to provide an excess of electrons in an n-type TFET. Similarly, in some embodiments, the materials used to form the inner layer 216 can include Si, which can be heavily doped with acceptor impurities such as boron or gallium. In some embodiments, the inner layer 216 is made of Ge, SiGe, GaAs, InAs, or InGaAs. In some embodiments, both inner layer 216 and the bottom dielectric isolation layer 212a are made of SiGe. In such embodiments, the Ge content in the bottom dielectric isolation layer 212a is higher than the Ge content in the inner layer 216.

The outer layer 214 can be a narrow band gap dielectric material. Similar to the inner layer 216, the outer layer 214 can be deposited using techniques such as thermal oxidation, chemical vapor deposition (CVD), or physical vapor deposition (PVD).

FIG. 2B illustrates a TFET device 200 after a gate structure is formed. The gate structure can include the dummy poly-silicon gate stack 218, which can be covered by the capping layer 220. In some embodiments, the capping layer 220 can be conformally deposited over the gate stack 218 using, for example, atomic layer deposition (ALD), although other conformal deposition processes are within the contemplated scope of the present disclosure. The capping layer 220 can be made of any suitable material, such as, for example, a low-k dielectric or an oxide (e.g., SiO2). In some embodiments, heavily doped regions of silicon (n+ or p+) or other semiconductor materials, such as germanium (Ge), silicon germanium (SiGe), gallium arsenide (GaAs), indium arsenide (InAs), and indium gallium arsenide (InGaAs) can be used as source or drain electrodes.

FIG. 2C illustrates a TFET device 200 after the bottom dielectric isolation layer 212a is removed, which is shown by cavity 212b.

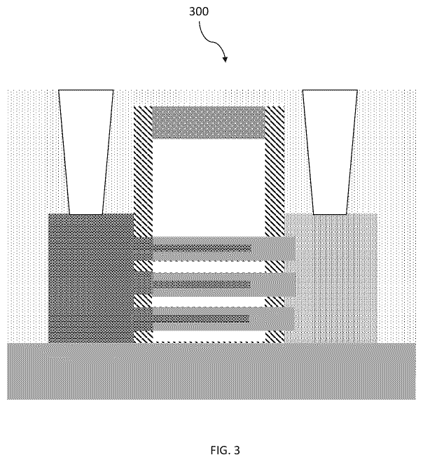

Referring to FIG. 2D now, a TFET device 200 after a spacer 222 is applied is illustrated. The spacer 222 can be applied to the sidewalls of the gate structure. The spacer can further be deposited into the cavity after removing the bottom dielectric isolation layer 212a to cover substrate layer 210. The spacer-covered substrate is shown as 212c in FIG. 3D. In some embodiments, Silicon dioxide, silicon nitride, polysilicon, silicon boron nitride, and metal silicides (such as titanium silicide or tungsten silicide) can be used as insulating materials for spacers. The spacer can be deposited using techniques such as thermal oxidation or chemical vapor deposition (CVD).

FIG. 2E illustrates a TFET device 200 after nanosheets pull down, which is a process in which portions of the nanosheets (the alternating layers) are removed from the top layer down to the spacer layer 222. As a result of the nanosheet pull-down, only the vertical sidewalls of the nanosheets are exposed.

Referring to FIG. 2F now, a TFET device 200 after inner spacer formation is shown, consistent with an illustrative embodiment. The spacer 222 is applied to the sidewalls of the nanosheets and covers the inner layer. Upon completion of the spacer formation, only the sidewalls of the outer layer remain exposed.

FIG. 2G illustrates the formation of an OPL 224 over a drain side of the TFET device 200, consistent with an illustrative embodiment. The OPL 224 can include a photo-sensitive organic polymer having a light-sensitive material that, when exposed to electromagnetic (EM) radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene (BCB). In some embodiments, the OPL 224 can include any organic polymer and a photoactive compound having a molecular structure that can attach to the molecular structure of the organic polymer. In some embodiments, the OPL 224 material is selected to be compatible with an overlying antireflective coating (not shown) and/or an overlying photoresist (not shown). In some embodiments, the OPL 224 can be applied using spin coating technology, although other techniques are within the contemplated scope of the present disclosure.

FIG. 2H illustrates the TFET device 200 after the outer layers are laterally recessed, consistent with an illustrative embodiment. In this step, the channel region on the source side of the TFET device 200 is recessed laterally. This lateral recessing process creates multiple channel surfaces within the trench 214b, resulting in multiple channel surfaces. As a result, the effective channel area is increased and efficient charge carrier transport through the tunneling mechanism is facilitated.

FIG. 2I illustrates the TFET device 200 after the OPL is removed. In some embodiments of the present disclosure, the OPL 224 can be removed using, for example, ashing or any other suitable removal technique.

Referring to FIG. 2J, the TFET device 200 is illustrated after the inner layer is epitaxially grown inside the recesses. In some embodiments, following the lateral recessing of the channel region, an epitaxial growth process is employed to deposit a source-side epitaxial layer inside the recesses. This growth results in the formation of three junction areas, namely the top, bottom, and right junctions. The source side epitaxial layer enables the tunneling mechanism by providing the outer layer 214. The outer layer 214 can be a narrow bandgap material to promote efficient charge carrier tunneling across the channel region. The remaining void space 226 inside the recesses is subsequently filled with the inner layer materials.

FIG. 2K illustrates the TFET 200 after the source and drain regions are formed, consistent with an illustrative embodiment. In various embodiments, the source region 230 and the drain regions are epitaxially grown on opposite sides of the channel region. The source and drain regions 230 and 240 can be formed by depositing on top of the heavily doped regions. A gate stack 250, which can include insulators and gate metals, is formed above the source and drain regions 230 and 240. High-k dielectric materials can be used as gate insulators. In some embodiments, such high-k materials can include hafnium oxide (HfO₂) or aluminum oxide (Al₂O₃), which allow for better gate control, reduce gate leakage, and enable the continued scaling of transistor dimensions. In additional embodiments, the gate stack 250 may be metalized with metals such as tungsten (W), aluminum (Al), or copper (Cu) to enhance conductivity and reduce resistive losses.

In an embodiment, the materials used to form the source and drain regions 230 and 240 in TFET device 200 can include Silicon (Si). For n-type TFET devices, the source and drain regions can be doped with donor impurities such as phosphorus or arsenic to provide an excess of electrons. In p-type TFET devices, acceptor impurities such as boron or gallium can be used to create regions with an excess of holes. In addition to silicon, other semiconductor materials can be employed in TFET device 200. For example, in some embodiments, III-V compound semiconductors such as gallium arsenide (GaAs) or indium phosphide (InP) can be utilized to provide higher carrier mobility compared to silicon. In some embodiments, one or both of the source region 230 and the drain region 240 are made of Ge, SiGe, GaAs, InAs, or InGaAs. Further, in some embodiments, one or both of the source region 230 and the drain region 240 can be doped to a level of about 1E20/cm³ to about 1E21/cm³. In various embodiments, the source region material is grown within the remaining portions of the recesses, such that while the nanosheets can be seen as extensions of the source region, the inner layer of the nanosheets does not directly contact the drain region.

Referring to FIG. 3 now, a TFET device 300 in accordance with an embodiment of the present disclosure is illustrated. In some embodiments, and in the absence of the bottom dielectric isolation layer, the substrate layer is covered by the nanosheets and is in direct contact with the source and drain regions.

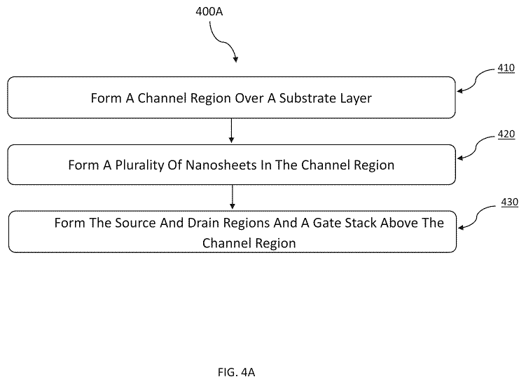

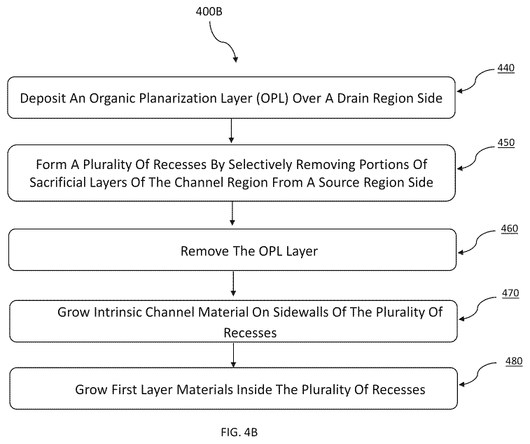

FIGS. 4A and 4B illustrate block diagrams of a method for the fabrication of the TFET device. Referring to FIG. 4A now, the method 400A can begin when a channel region over a substrate layer is formed, as shown by block 410. The method 400A can proceed when a plurality of nanosheets in the channel region is formed, as shown by block 420. The plurality of nanosheets can protrude from a source region toward a drain region. In an embodiment, each nanosheet can include a first layer encapsulated by a narrow band gap material layer. In some embodiments, the first layer is not in direct contact with the drain region. As shown by block 430, the method can proceed further when the source and drain regions and a gate stack above the channel region are formed.

Referring to FIG. 4B now, a method 400B for the formation of the nanosheets is shown. As shown by block 440, the method begins when an organic planarization layer (OPL) is formed over a drain region side. The method 400B can continue when a plurality of recesses are formed by selectively removing portions of the channel region from a source region side, while the drain region side is intact, as shown by block 450. As shown by block 460, method 400B can proceed when the OPL layer is removed. Method 400B can proceed when channel materials are grown on the sidewalls of the plurality of recesses, as shown by block 470. Finally, and as shown by block 480, method 400B continues when the first layer of materials inside the plurality of recesses is grown to form the plurality of nanosheets.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A Tunnel Field-Effect Transistor (TFET) device, the TFET device comprising:
a substrate layer;
a gate stack on top of the substrate layer;
a source region and a drain region above the substrate layer;
a channel region underneath the gate stack; and
a plurality of nanosheets in the channel region protruding from the source region, wherein:
each nanosheet of the plurality of nanosheets comprises a first layer encapsulated by a narrow band gap material layer; and
the first layer is not in direct contact with the drain region.

2. The TFET device of claim 1, wherein:
each nanosheet of the plurality of nanosheets is attached to the source region on a first side of the nanosheet; and
a second side, a top side and a bottom side of each nanosheet of the plurality of nanosheets are encapsulated by the channel region.

3. The TFET device of claim 1, wherein at least one of the source, the drain, and the channel regions includes Ge, SiGe, GaAs, InAs, and InGaAs.

4. The TFET device of claim 1, wherein two or more of the source, the drain, and the channel regions are homojunctions.

5. The TFET device of claim 1, wherein the source, drain, and channel regions are heterojunctions.

6. The TFET device of claim 1, wherein tunneling occurs via a top surface, a bottom surface, and a side surface of each nanosheet of the plurality of nanosheets.

7. The TFET device of claim 1, wherein the first layer and the source region comprise a same material.

8. The TFET device of claim 1, wherein a thickness of the channel region is substantially 5 nanometers to substantially 10 nanometers.

9. A method for forming a Tunnel Field-Effect Transistor (TFET) device, the method comprising:
forming a channel region over a substrate layer;
forming a plurality of nanosheets in the channel region protruding from a source region toward a drain region, wherein:
each nanosheet of the plurality of nanosheets comprises a first layer encapsulated by a narrow band gap material layer; and
the first layer is not in direct contact with the drain region; and
forming the source and drain regions and a gate stack above the channel region.

10. The method of claim 9, wherein forming the plurality of nanosheets comprises:
depositing an organic planarization layer (OPL) over a drain region side;
forming a plurality of recesses by selectively removing portions of the channel region from a source region side, while the drain region side is intact;
removing the OPL layer;
growing channel material on sidewalls of the plurality of recesses; and
growing first layer materials inside the plurality of recesses to form the plurality of nanosheets.

11. The method of claim 10, wherein each recess of the plurality of recesses is arranged in a direction that is parallel to a surface of the substrate layer.

12. The method of claim 9, further comprising forming an insulating layer to separate the gate stack from the channel region.

13. The method of claim 9, wherein:
each nanosheet of the plurality of nanosheets is attached to the source region on a first side of the nanosheet; and
a second side, a top side, and a bottom side of each nanosheet of the plurality of nanosheets are encapsulated by the channel region.

14. The method of claim 9, wherein at least one of the source, the drain, and the channel regions includes Ge, SiGe, GaAs, InAs, and InGaAs.

15. The method of claim 9, wherein two or more of the source, the drain, and the channel regions are homojunction.

16. The method of claim 9, wherein the source, the drain, and the channel regions are heterojunctions.

17. The method of claim 9, wherein tunneling occurs via a top surface, a bottom surface, and a side surface of each nanosheet of the plurality of nanosheets.

18. The method of claim 9, wherein the plurality of nanosheets is formed by an epitaxial growth technique.

19. The method of claim 9, wherein a thickness of the channel region is substantially 5 nanometers to substantially 10 nanometers.

20. A Tunnel Field-Effect Transistor (TFET) device, the TFET device comprising:
an isolating layer over a substrate layer;
a gate stack above the isolating layer;
a source and a drain region over the isolating layer;
a channel region underneath the gate stack; and
a plurality of nanosheets in the channel region protruding from the source region, wherein each nanosheet of the plurality of nanosheets comprises source region material encapsulated by a narrow band gap material.
